(19) United States
(12) Patent Application Publication
(10) Pub. No.: US 2014/0007941 A1
(43) Pub. Date: Jan. 9, 2014

(54) PROTECTIVE SHEET FOR SOLAR CELL, METHOD FOR MANUFACTURING THE SAME, BACK SHEET MEMBER FOR SOLAR CELL, BACK SHEET FOR SOLAR CELL AND SOLAR CELL MODULE

(71) Applicant: FUJIFILM Corporation, Tokyo (JP)

(72) Inventors: Shin OZAWA, Kanagawa (JP); Naoya IMAMURA, Kanagawa (JP); Yusuke AKASAKI, Kanagawa (JP)

(73) Assignee: FUJIFILM Corporation, Tokyo (JP)

(21) Appl. No.: 14/020,337

(22) Filed: Sep. 6, 2013

Related U.S. Application Data
(63) Continuation of application No. PCT/JP2012/055616, filed on Mar. 6, 2012.

(30) Foreign Application Priority Data
Mar. 7, 2011 (JP) 2011-049492

(51) Int. Cl. H01L 31/0216; H01L 31/18

(52) U.S. Cl. CPC H01L 31/02167; H01L 31/18
USPC 136/259; 428/335; 428/423.1; 428/421; 428/424.4; 524/507; 427/74

(57) ABSTRACT

A protective sheet for a solar cell including a base material film, and an olefin-based polymer layer which is disposed on at least one surface of the base material film and has at least one olefin-based binder, in which the olefin-based polymer layer contains 8 mass % or less of an ether-based polyurethane resin with respect to the olefin-based binder, has a favorable adhesive force to a sealing material and a favorable adhesive force to a sealing material even after aged in a hot and humid environment.

### CROSS-REFERENCE TO RELATED APPLICATIONS

This application is a continuation application of International Application No. PCT/JP2012/055616, filed Mar. 6, 2012, which in turn claims the benefit of priority from Japanese Application No. 2011-049492, filed Mar. 7, 2011, the disclosures of which applications are incorporated by reference herein in their entirety.

### BACKGROUND OF THE INVENTION

1. Field of the Invention

The present invention relates to a protective sheet for a solar cell, a method for manufacturing the same, a back sheet member for a solar cell, a back sheet for a solar cell and a solar cell module.

2. Background Art

In general, a solar cell module in which crystalline silicon, amorphous silicon or the like is used for solar cell elements is manufactured using a lamination method or the like in which a transparent front substrate on a side on which solar light enters, a cell-side substrate in which a solar cell element as a photovoltaic element is sealed with a sealing material, a rear surface protective sheet layer (back sheet for the solar cell) and the like are sequentially stacked, sucked in a vacuum, and hot-pressed. Since a solar cell is placed in an environment exposed to direct sun light and rain, such as on the roof, for a long period of time, the respective layers that configure a solar cell module are required to have a variety of functions typically including durability, particularly durability in a hot and humid environment.

In the past, glass was frequently used for the transparent front substrate or the back sheet for a solar cell; however, in recent years, there has been a demand for use of a protective sheet for a solar cell in which a base material mainly including a resin film is used for the front substrate or the back sheet for a solar cell since a variety of functions can be added by stacking functional layers and the cost can be reduced by decreasing the weight of the solar cell module.

The above protective sheets for a solar cell frequently form a laminate of a variety of functional layers as described above. Examples of typical functional layers include an adhesive layer for closely attaching the laminate to the sealing material, a white layer for increasing the expression efficiency of the solar cell elements by supplying a reflection function of solar light which has transmitted through the transparent front substrate and the cell-side substrate, a weather-resistant layer preferably installed on the outermost layer of the protective sheet for a solar cell, and the like.

Although there are a variety of functions that the protective sheet for a solar cell is required to have as described above, among the functions, there is a particular demand for durability, particularly durability in a hot and humid environment which has a direct influence on the service life of the solar cell module. Particularly, from the viewpoint of the durability of the solar cell module, particularly durability in a hot and humid environment, it is most important to prevent the peeling of the sealing material from the protective sheet for a solar cell and the intrusion of moisture into the cell-side substrate. That is, there is a demand for a protective sheet for a solar cell having a favorable durability with a sealing material used in a solar cell module, particularly a favorable adhesion in a hot and humid environment.

However, for the outmost layer of the back sheet for a solar cell which is in contact with the sealing material used in the solar cell module, the adhesion in an ordinary environment let alone the adhesion in a hot and humid environment have been rarely studied. For example, Patent Literature 1 simply describes that a back sheet for a solar cell is stacked on a filler (sealing material) made of an ethylene-vinyl acetate copolymer (hereinafter also referred to as EVA) and does not describe how the back sheet is attached to the filler. In addition, Patent Literature 1 describes a variety of aspects of a layer regarding the outermost layer of the back sheet for a solar cell on the sealing material side, but does not describe the adhesion to the sealing material. In addition, in Patent Literature 2, a back sheet for a solar cell and a sealing material used in a solar cell module are stacked through an extrusion resin layer made of a resin composition and are hot-pressed, but there is no description of the composition or properties of the extrusion resin layer.

Meanwhile, an example in which an adhesive layer is provided between a sealing material used in a solar cell module and the outermost layer of a back sheet for a solar cell on a sealing material side is described. For example, Patent Literature 3 describes a back sheet for a solar cell in which a deposited film of an inorganic oxide is provided on a single surface of a base material film, and heat-resistant polypropylene-based resin films including a whitening agent and an ultraviolet absorbent are stacked on both surfaces of the base material film provided with the deposited film of the inorganic oxide, and Patent Literature 3 discloses an aspect in which a sealing material made of EVA is stacked on the outermost layer of the back sheet for a solar cell using an acrylic adhesive layer in examples.

Meanwhile, in recent years, an example in which the material of the outermost layer of the back sheet for a solar cell on the sealing material side is studied and the direct adhesion between the sealing material used in the solar cell module and the outermost layer of the back sheet for a solar cell on the sealing material side is studied has been also known to a slight extent (refer to Patent Literature 4). Patent Literature 4 describes an aspect in which the back sheet for a solar cell configured of at least two or more layers including a weather-resistant base material film has an adhesive coated layer colored with a white pigment mainly including titanium oxide on an innermost surface that is adhered to a filler configuring a solar cell module of the solar cell back sheet. Patent Literature 4 describes that an acrylic resin, an epoxy-based resin, a phenol-based resin, a polyester-based resin, an urethane-based resin, a styrene-based resin, a silicone-based resin or a denaturant thereof is preferably used as a resin for the adhesive coated layer having adhesion to EVA, and the resin preferably includes a polyacrylic resin among the above. In addition, Patent Literature 4 only discloses an aspect in which an adhesive coated layer including an acrylic resin or an acrylic acid resin into which a polyester skeleton has been introduced in examples.

### CITATION LIST

### Patent Literature

Patent Literature 1: Japanese Patent No. 2006-073793
Patent Literature 2: JP-A-2006-210557
Patent Literature 3: JP-A-2007-306006
Patent Literature 4: JP-A-2010-109240

### SUMMARY OF INVENTION

However, when the inventors manufactured solar cell modules using the methods described in Patent Literatures 3 and 4, and, furthermore, aged the solar cell modules in a hot and humid environment, the durability between the sealing material in the solar cell module and the protective sheet for a solar cell, particularly adhesion in a hot and humid environment still remained at an unsatisfactory level.

In addition to what has been described above, as a result of attempts to manufacture films through coating particularly using a so-called olefin-based resin such as a polypropylene-based resin described in Patent Literature 3, the inventors found that the olefin-based resin was easily attached to a manufacturing apparatus during manufacturing of a film through coating, and the yield became poor when a film was continuously manufactured such that there was a new problem in that it became impossible to stably manufacture a film for a long period of time. In addition, it was found that, even when attempts were made to wash the attachment of the olefin-based resin to the manufacturing apparatus when manufacturing a film through coating, the washability was poor, and it was difficult to wash the attachment. In addition, Patent Literature 3 describes nothing about the above problems and means for solving the problems, and it was found that there is a demand for solving the new problem.

Therefore, objects of the invention are to provide a protective sheet for a solar cell having a favorable adhesive force to a sealing material and having a favorable adhesive force to a sealing material even after aged in a hot and humid environment, and to provide a method for manufacturing a solar cell protective sheet in which the solar cell protective sheet can be stably manufactured for a long period of time and washability can be enhanced.

As a result of thorough studies for the purpose of achieving the above objects, the inventors found that the above objects can be achieved by combining a binder having a specific skeleton and a binder having an another specific skeleton at a specific ratio, and using the combination.

That is, the configuration of the invention, which is specific means for achieving the object, is as follows.

[1] A protective sheet for a solar cell including a base material film; and an olefin-based polymer layer which is disposed on at least one surface of the base material film and contains at least one olefin-based binder, in which the olefin-based polymer layer contains 8 mass % or less of an ether-based polyurethane resin with respect to the olefin-based binder.

[2] In the protective sheet for a solar cell according to [1], the olefin-based polymer layer is a colored layer containing a coloring pigment.

[3] In the protective sheet for a solar cell according to [2], a surface of the base material film on which the colored layer is disposed has a light reflectivity of 70% or more at a wavelength of 550 nm, and the coloring pigment is titanium oxide.

[4] In the protective sheet for a solar cell according to any one of [1] to [3], a thickness of the olefin-based polymer layer is 30 μm or less.

[5] The protective sheet for a solar cell according to any one of [1] to [4] further includes at least one separate layer between the olefin-based polymer layer and the base material film.

[6] The protective sheet for a solar cell according to any one of [1] to [5] further includes a weather-resistant layer including at least one of a fluororesin and a silicone-acryl composite resin on a surface of the base material film opposite to a surface on which the olefin-based polymer layer is disposed.

[7] A method for manufacturing a protective sheet for a solar cell including coating a composition for forming an olefin-based polymer layer which contains at least one olefin-based binder, on at least one surface of a base material film or a separate layer which may be arbitrarily provided on the base material film, in which the composition for forming the olefin-based polymer layer contains 8 mass % or less of an ether-based polyurethane resin with respect to the olefin-based binder.

[8] In the method for manufacturing a protective sheet for a solar cell according to [7], the composition for forming the olefin-based polymer layer is a composition for forming a colored layer containing a coloring pigment.

[9] In the method for manufacturing a protective sheet for a solar cell according to [7] or [8], the coloring pigment is titanium oxide.

[10] The method for manufacturing a protective sheet for a solar cell according to any one of [7] to [9] further includes coating a composition for forming a basecoat layer on the base material film before coating the composition for forming the olefin-based polymer layer.

[11] The method for manufacturing a protective sheet for a solar cell according to any one of [7] to [10] further includes coating a composition for forming a weather-resistant layer including at least one of a fluororesin and a silicone-acryl composite resin on a surface of the base material film opposite to a surface on which the composition for forming the olefin-based polymer layer is coated.

[12] In the method for manufacturing a protective sheet for a solar cell according to any one of [7] to [11], a content of the ether-based polyurethane resin included in the composition for forming the olefin-based polymer layer is 2 mass % to 5 mass % with respect to the olefin-based binder.

[13] In the method for manufacturing a protective sheet for a solar cell according to any one of [7] to [12], the olefin-based binder included in the composition for forming the olefin-based polymer layer has an elastic modulus of 320 MPa or less.

[14] A protective sheet for a solar cell manufactured using the method for forming a protective sheet for a solar cell according to any one of [7] to [13].

[15] A back sheet member for a solar cell or a back sheet for a solar cell including the protective sheet for a solar cell according to any one of [1] to [6] and [14].

[16] A laminate for a solar cell including the protective sheet for a solar cell according to any one of [1] to [6] and [14]; and a polymer layer which is in direct contact with at least a surface of the protective sheet for a solar cell on the olefin-based polymer layer side and includes an ethylene-vinyl acetate copolymer or polyvinyl butyral.

[17] A solar cell module including a transparent front substrate on a side on which sun light enters; a solar cell element; a sealing material that seals the solar cell element; and a back sheet for a solar cell which is disposed on the sealing material on an opposite side to the front substrate and is adhered to the sealing material, in which the back sheet for a solar cell includes the back sheet member for a solar cell or the back sheet for a solar cell according to [15], and the olefin-based polymer layer in the back sheet member for a solar cell or the back sheet for a solar cell is directly adhered to the sealing material.

[18] A solar cell module including a transparent front substrate on a side on which sun light enters; a solar cell element; a sealing material that seals the solar cell element; and a back sheet for a solar cell which is disposed on the sealing material on an opposite side to the front substrate and is adhered to the sealing material, in which the laminate for a solar cell according to [16] is included as the back sheet for a solar cell and the sealing material.

According to the invention, a protective sheet for a solar cell having a favorable adhesive force to a sealing material and a favorable adhesive force to a sealing material even after aged in a hot and humid environment is provided. In addition, a method for manufacturing a solar cell protective sheet in which the solar cell protective sheet can be stably manufactured for a long period of time and washability can be enhanced is provided.

### BRIEF DESCRIPTION OF DRAWING

FIG. 1 is a cross-sectional view schematically illustrating an example of a configuration of a module for a solar cell of the invention.

### MODE FOR CARRYING OUT THE INVENTION

Hereinafter, a protective sheet for a solar cell of the invention, a method for manufacturing the same, materials used therefor and the like will be described in detail.

The description of configuration requirements described below may be based on typical embodiments of the invention, but the invention is not limited to the above embodiments. Meanwhile, numeric ranges expressed using “to” in the present specification include numeric values described before and after “to” as the lower limit value and the upper limit value.

[Protective Sheet for Solar Cell and Method for Manufacturing the Same]

The protective sheet for a solar cell of the invention includes a base material film, and an olefin-based polymer layer which is disposed on at least one surface of the base material film and has at least one binder, which is an olefin-based binder, in which the olefin-based polymer layer contains 8 mass % or less of an ether-based polyurethane resin with respect to the olefin-based binder.

The above configuration makes the adhesive force of the protective sheet for a solar cell of the invention to a sealing material favorable before and after aged in a hot and humid environment. In addition, the above characteristics of the protective sheet for a solar cell of the invention enables a solar cell module in which the protective sheet for a solar cell of the invention is used to stably hold powder generation performances for a long period of time without peeling or the like caused by aging in a hot and humid environment using the favorable adhesive force of the protective sheet for a solar cell of the invention to the sealing material.

In addition, the method for manufacturing a protective sheet for a solar cell of the invention includes a step of coating a composition for forming an olefin-based polymer layer which has at least one binder, which is an olefin-based binder, on at least one surface of a base material film or a separate layer which may be arbitrarily provided on the base material film, in which the composition for forming the olefin-based polymer layer contains 8 mass % or less of an ether-based polyurethane resin with respect to the olefin-based binder.

Hereinafter, the protective sheet for a solar cell and the method for manufacturing the same of the invention will be described.

<Configuration of the Protective Sheet for a Solar Cell>

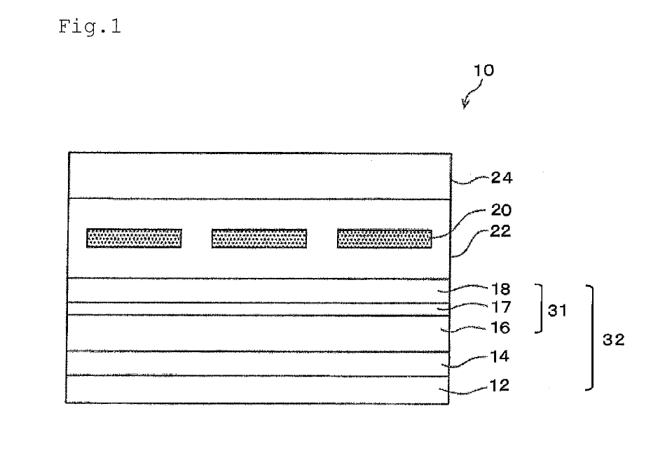

FIG. 1 illustrates the description of the protective sheet for a solar cell of the invention, a back sheet member for a solar cell in which the protective sheet for a solar cell is used, a back sheet for a solar cell and a laminate for a solar cell, and an example of the configuration of a solar cell module for which the protective sheet for a solar cell of the invention is used. The protective sheet for a solar cell 31 is provided with an olefin-based polymer layer 18 on one surface of a base material film 16. In a case in which the protective sheet for a solar cell of the invention is used with no weather-resistant layer provided, the protective sheet is also referred to as the back sheet member for a solar cell of the invention. Furthermore, a separate layer 17 may be provided between the base material film 16 and the olefin-based polymer layer 18.

Weather-resistant layers are preferably provided on the other surface of the base material film 16. The base material film 16 is preferably provided with two weather-resistant layers of a first weather-resistant layer 14 and a second weather-resistant layer 12. When the weather-resistant layers 16 are provided, the protective sheet for a solar cell of the invention can be used as a back sheet for a solar cell 32 as it is.

In the back sheet for a solar cell of the invention, the olefin-based polymer layer 18 has a favorable adhesion to a sealing material 22 that seals a solar cell element 20 of a solar cell module 10 even after aged in a hot and humid environment. Therefore, it is not necessary to provide an adhesive layer between the olefin-based polymer layer 18 of the protective sheet for a solar cell of the invention and the sealing material 22 of the solar cell module 10 from the viewpoint of the adhesion even after the olefin-based polymer layer is aged in a hot and humid environment.

Meanwhile, the solar cell module 10 of the invention preferably has a transparent front substrate 24 disposed on the sealing material 22 on an opposite side of the protective sheet for a solar cell of the invention.

<The Respective Configuration Members of the Protective Sheet for a Solar Cell>

Hereinafter, preferable aspects of the respective configuration members that configure the protective sheet for a solar cell of the invention will be described.

(Base Material Film)

The protective sheet for a solar cell of the invention has the base material film.

The material of the base material film is not particularly limited, and examples thereof include polyolefins such as polyesters, polypropylene and polyethylene; fluorine-based polymers such as polyvinyl fluoride; and the like.

Among the above, the material of the base material film is preferably polyester from the standpoint of cost, mechanical strength and the like.

The polyester is preferably a linear saturated polyester synthesized from an aromatic diacid or an ester-forming derivative thereof and a diol or an ester-forming derivative thereof.

Specific examples of the linear saturated polyester include polyethylene terephthalate (PET), polyethylene isophthalate, polybutylene terephthalate, poly(1,4-cyclohexylene dimethylene teraphthalate) and polyethylene-2,6-naphthalate.

Among the above, polyethylene terephthalate or polyethylene-2,6-naphthalate is particularly preferable from the standpoint of the balance between dynamic properties and cost.

The polyester may be a homopolymer or a copolymer. Furthermore, the polyester may be a mixture of the polyester and a small amount of another resin, for example, polyimide.

The content of a carboxylic group in the polyester is preferably 50 equivalent amount/t or less and more preferably 35 equivalent amount/t or less with respect to the polyester. When the content of the carboxylic group is 50 equivalent amount/t or less, it is possible to hold hydrolysis resistance and to suppress a decrease in the strength to a small extent when the base material film is aged in a hot and humid environment. The lower limit of the content of the carboxylic group is desirably 2 equivalent amount/t from the standpoint of holding the adhesion to a layer formed in the polyester (for example, a white layer).

The content of the carboxylic group in the polyester can be adjusted by the kind of a polymerization catalyst and film-manufacturing conditions (film-manufacturing temperature or time) used.

As the polymerization catalyst when polymerizing the polyester, a Sb-based, Ge-based or Ti-based compound is preferably used from the viewpoint of suppressing the content of the carboxylic group to a predetermined range or less, and a Ti-based compound is particularly preferable. In a case in which a Ti-based compound is used, the polyester is preferably polymerized using the Ti-based compound in a range of 1 ppm to 30 ppm and more preferably 3 ppm to 15 ppm as a catalyst. When the fraction of the Ti-based compound is in the above range, it is possible to adjust a terminal carboxylic group in the following range, and it is possible to maintain the hydrolysis resistance of a polymer base material at a low level.

For the synthesis of the polyester using the Ti-based compound, the methods described in, for example, JP-B-8-301198, Japanese Patent No. 2543624, Japanese Patent No. 3335683, Japanese Patent No. 3717380, Japanese Patent No. 3897756, Japanese Patent No. 3962226, Japanese Patent No. 3979866, Japanese Patent No. 3996871, Japanese Patent No. 4000867, Japanese Patent No. 4053837, Japanese Patent No. 4127119, Japanese Patent No. 4134710, Japanese Patent No. 4159154, Japanese Patent No. 4269704, Japanese Patent No. 4313538 and the like can be applied.

The polyester is preferably polymerized in a solid state after polymerization. Thereby, a preferable content of the carboxylic group can be achieved. The solid-state polymerization may be a continuous method (a method in which a resin is charged in a tower, is made to slowly stay for a predetermined period of time under heating, and then discharged) or a batch method (a method in which a resin is injected into a container and heated for a predetermined period of time). Specifically, the methods described in Japanese Patent No. 2621563, Japanese Patent No. 3121876, Japanese Patent No. 3136774, Japanese Patent No. 3603585, Japanese Patent No. 3616522, Japanese Patent No. 3617340, Japanese Patent No. 3680523, Japanese Patent No. 3717392, Japanese Patent No. 4167159 and the like can be applied to the solid layer polymerization.

The temperature of the solid-state polymerization is preferably 170° C. to 240° C., more preferably 180° C. to 230° C., and still more preferably 190° C. to 220° C. In addition, the solid-state polymerization time is preferably 5 hours to 100 hours, more preferably 10 hours to 75 hours, and still more preferably 15 hours to 50 hours. The solid-state polymerization is preferably carried out in a vacuum or in a nitrogen atmosphere.

The base material film is preferably a biaxial stretched film obtained by, for example, melting and extruding the polyester into a film shape, cooling and solidifying the polyester in a casting drum so as to produce an unstretched film, stretching the unstretched film in the longitudinal direction once or twice or more at a glass transition temperature Tg° C. to (Tg+60)° C. so that the total magnification becomes 3 times to 6 times, and then stretching the film in the width direction at Tg° C. to (Tg+60)° C. so that the magnification becomes 3 times to 5 times.

Furthermore, the base material film may be a film which has been subjected to a thermal treatment at 180° C. to 230° C. for 1 second to 60 seconds as necessary.

The thickness of the base material film is preferably 25 μm to 300 μm, and more preferably 120 μm to 300 μm. When the thickness is 25 μm or more, a sufficient dynamic strength can be obtained, and, when the thickness is set to 300 μm or less, the base material film is advantageous in terms of costs.

Particularly, when the hydrolysis resistance is enhanced, a polyester base material tends to be available for a long period of time in a hot and humid environment, and, in the invention, in a case in which the thickness of the base material film is 120 μm to 300 μm, and the content of the carboxylic group in the polyester is 2 equivalent amount/t to 50 equivalent amount/t, an effect of further improving durability in a hot and humid environment is exhibited.

(Olefin-Based Polymer Layer)

The protective sheet for a solar cell of the invention has an olefin-based polymer layer which is disposed on at least one surface of the base material film and contains at least one binder which is an olefin-based binder, in which the olefin-based polymer layer contains 8 mass % or less of an ether-based polyurethane resin with respect to the olefin-based binder.

Hereinafter, there are cases in which the binder which is an olefin-based binder will be referred to as a main binder, and the ether-based polyurethane resin will be referred to as an additive binder.

The film thickness of the olefin-based polymer layer is preferably 30 μm or less, more preferably 1 μm to 20 μm, particularly preferably 1.5 μm to 10 μm, and more particularly preferably 2 μm to 8 μm. When the film thickness is set to 1 μm or more, decorativeness or reflectivity can be sufficiently developed, and, when the film thickness is set to 30 μm or less, the deterioration of the surface state is suppressed, and the adhesion to the sealing material after the protective film is aged in a hot and humid environment can be improved.

—Binder—

In the invention, as the binder for the olefin-based polymer layer, at least one binder which is an olefin-based binder is used.

Examples of the kind of a main chain skeleton of the olefin-based binder include ethylene-acrylic acid ester-maleic anhydride (and/or acrylic acid) copolymers, ethylene-propylene-maleic anhydride (and/or acrylic acid) copolymers, ethylene-butene-maleic anhydride (and/or acrylic acid) copolymers, propylene-butene-maleic anhydride (and/or acrylic acid) copolymers, ethylene-propylene-butene-maleic anhydride copolymers, ethylene-propylene-acrylic acid ester-maleic anhydride (and/or acrylic acid) copolymers, ethylene-butene-acrylic acid ester-maleic anhydride (and/or acrylic acid) copolymers, propylene-butene-acrylic acid ester-maleic anhydride (and/or acrylic acid) copolymers, ethylene-propylene-butene-acrylic acid ester-maleic anhydride (and/or acrylic acid) copolymers and the like.

The elastic modulus of the olefin-based binder used in the invention is preferably 320 MPa or less, and the elastic modulus of the olefin-based binder is more preferably 10 MPa to 250 MPa, particularly preferably 20 MPa to 150 MPa, and more particularly preferably 30 MPa to 100 MPa.

In particular, when the olefin-based binder included in the composition for forming the olefin-based polymer layer has an elastic modulus of 320 MPa or less, the method for manufacturing a solar cell protective sheet of the invention exhibits a particularly significant effect, the solar cell protective sheet can be stably manufactured for a long period of time, and washability can be enhanced.

The shape or use pattern of the olefin-based binder is also not particularly limited as long as the polymer layer can be formed. For example, the olefin-based binder may be a water-dispersible olefin-based resin or a meltable olefin-based resin. In addition, the olefin-based binder may be a crystalline olefin-based resin or a non-crystalline olefin-based resin.

In the invention, among the above, an olefin-based binder that is dispersible in a solvent is preferably used since the olefin-based polymer layer can be formed through coating and the adhesion to the sealing material after the protective sheet is aged in a hot and humid environment can be further improved. The olefin-based binder is more preferably dispersible in water.

The procurement method of the olefin-based binder is also not particularly limited, and may be commercially procured or may be synthesized. In addition, the elastic modulus of the olefin-based binder obtained in the invention may be controlled in a range by adding an additive.

Examples of the olefin-based binder used in the invention which can be commercially procured include ARROW BASE SE-1010 manufactured by Unitika Ltd., SD-1010; TC-4010 and TD-4010; HITECH S3148, S3121 and S8512 (manufactured by Toho Chemical Industry Co., Ltd.); CHEMIPEARL S-120, S-75N, V100, EV210H (all manufactured by Mitsui Chemicals, Inc.). Among the above, in the invention, ARROW BASE SE-1010 manufactured by Unitika Ltd. is preferably used.

The olefin-based binder used as the binder for the olefin-based polymer layer may be used solely, or a mixture of a plurality of the olefin-based binders may be used.

—Ether-Based Polyurethane Resin—

As the binder for the olefin-based polymer layer, 8 mass % or less of an ether-based polyurethane resin with respect to the olefin-based binder is included. Meanwhile, binders other than the olefin-based binder or the ether-based polyurethane resin may be included within the scope of the purport of the invention.

Examples of the ether-based polyurethane-based binder include SUPER FLEX 110 manufactured by Daiichi Kogyo Seiyaku Co., Ltd. and the like.

The amount of the ether-based polyurethane resin added to the olefin-based binder is 8 mass % or less, preferably 2 mass % to 8 mass %, and more preferably 2 mass % to 5 mass % from the viewpoint of improving the washability of a manufacturing apparatus in the method for manufacturing a solar cell protective sheet of the invention, which will be described below.

The ratio (mass ratio) of the olefin-based binder to the other binders is preferably 50:50 to 100:0, and more preferably 80:20 to 100:0.

—Coloring Pigment—

In the protective sheet for a solar cell of the invention, the olefin-based polymer layer is preferably a colored layer containing a coloring pigment.

A first function of the colored layer is to increase the power generation efficiency of the solar cell module by reflecting light of incident light, which has reached the back sheet without being used for power generation in the solar battery cell, so as to return the light to the solar battery cell. A second function is to improve the decorativeness of the appearance of the solar cell module when seen from the surface side. In general, when the solar cell module is seen from the surface side, the back sheet is seen around the solar battery cell, and the appearance can be improved by providing a colored layer on the back sheet so as to improve the decorativeness.

The coloring pigment used in the olefin-based polymer layer is not particularly limited, may be selected depending on required reflection properties, design properties and the like, and may be an inorganic pigment or an organic pigment. For example, a white pigment can be preferably used.

Examples of the inorganic pigment include titanium oxide, barium sulfate, silicon oxide, aluminum oxide, magnesium oxide, calcium carbonate, kaolin, talc, ultramarine, iron blue, carbon black and the like, and titanium oxide is preferable from the viewpoint of reflection properties, costs and the like.

Examples of the organic pigment include phthalocyanine blue, phthalocyanine green and the like.

When, for example, a white pigment is used as the coloring pigment, the colored layer has a function of increasing the power generation efficiency by irregularly reflecting light of solar light incident from the front surface of the solar cell module, which has passed through the cell, so as to return the light to the cell.

The light reflectivity of the surface of the base material film on which the colored layer is disposed (outermost surface) at a wavelength of 550 nm can be adjusted to be increased by controlling the content or layer thickness of the coloring pigment in the colored layer in the above or following numeric ranges.

The volume average particle diameter of the coloring pigment is preferably 0.03 μm to 0.8 μm, and more preferably 0.15 μm to 0.5 μm. When the volume average particle diameter of the coloring pigment is set in the above range, it is possible to suppress a decrease in the light reflection efficiency.

The volume average particle diameter of the coloring pigment is a value measured using MICROTRAC FRA manufactured by Honeywell Japan Inc.

A preferable content of the coloring pigment in the olefin-based polymer layer (colored layer) varies depending on the kind or average particle diameter of a coloring pigment to be used. When the content of the coloring pigment in the colored layer is not too small, reflection properties and design properties can be sufficiently developed, and, the content being not too large is preferable from the viewpoint of the adhesion to the sealing material. In the protective sheet for a solar cell of the invention, the content of the coloring pigment in the colored layer is 3 g/m² to 20 g/m², and more preferably 5 g/m² to 17 g/m² from the viewpoint of the above functions being sufficiently developed.

In the protective sheet for a solar cell of the invention, the volume fraction of the coloring pigment with respect to all the binder included in the colored layer is preferably 50% to 200%, and more preferably 90% to 150% from the same viewpoint.

—Other Additives—

The olefin-based polymer layer can further contain a variety of additives, such as a surfactant, fine particles other than the coloring pigment, an ultraviolet absorbent and an antioxidant, and, particularly, the composition for forming a colored layer for forming the colored layer is preferably prepared using a surfactant for the dispersion stability of the coloring pigment.

As the surfactant, for example, a well-known anionic, cationic or nonionic surfactant can be used, and specific examples thereof include DEMOL EP [manufactured by KAO Corporation], NAROACTY CL95 [manufactured by Sanyo Chemical Industries, Ltd.] and the like. The surfactant may be used solely or in a mixture of a plurality of kinds.

Examples of fine particles other than the coloring pigment include inorganic oxide fillers, such as silica, magnesium oxide and tin oxide. Among the above, tin oxide or silica is preferable due to the slight degradation of the adhesion when the protective film is exposed to a hot and humid atmosphere.

The volume average particle diameter of the inorganic oxide filler is preferably 10 nm to 700 nm, and more preferably 20 nm to 300 nm. When an inorganic oxide filler having an average particle diameter in the above range is used, a favorable high adhesion to a layer adjacent to the colored layer can be obtained, and the adhesion to an adjacent layer (more particularly preferably the sealing material of the solar cell module, for example, a sealing material layer including EVA) particularly in a hot and humid environment (for example, 85° C., relative humidity 85%) can be developed. Meanwhile, the volume average particle diameter of the inorganic oxide filler is a value measured using MICROTRAC FRA manufactured by Honeywell Japan Inc.

The shape of the fine particles other than the coloring pigment is not particularly limited, and fine particles having a spherical form, an irregular form, a needle-like form or the like can be used.

The content of the fine particles other than the coloring pigment in the colored layer is preferably 5 mass % to 400 mass %, and more preferably 50 mass % to 300 mass % with respect to the total mass of the binder resin in the colored layer. When the content of the fine particles is 5 mass % or more, the adhesion when the protective sheet is exposed to a hot and humid atmosphere and the adhesion to the sealing material of the solar cell module when the protective sheet is aged in a hot and humid environment are favorable, and, when the content is 400 mass % or less, it is possible to prevent the degradation of the surface state of the colored layer.

Meanwhile, as the fine particles other than the inorganic oxide filler, for example, calcium carbonate, magnesium carbonate and the like may be included.

—Formation of the Olefin-Based Polymer Layer—

The olefin-based polymer layer can be formed using a well-known method, and there is no particular limitation. For example, the film may be formed through solution casting or melting using the base material film as a support and stacked, or the olefin-based polymer layer that has been formed through solution casting on another support in advance and the base material film may be stacked through an adhesive or the like. Among the above, the protective sheet for a solar cell of the invention is preferably formed through solution casting using the base material film as a support. The method for forming a film through solution casting is not particularly limited, the film may be formed through casting or coating, and, in the protective sheet for a solar cell of the invention, the olefin-based polymer layer is preferably formed through coating.

Particularly, the method for manufacturing a protective sheet for a solar cell of the invention includes a step of coating a composition for forming an olefin-based polymer layer which has at least one binder, which is an olefin-based binder, on at least one surface of the base material film or a separate layer which may be arbitrarily provided on the base material film, in which the composition for forming the olefin-based polymer layer contains 8 mass % or less of an ether-based polyurethane resin with respect to the olefin-based binder. The above configuration enables to provide a method for manufacturing a solar cell protective sheet in which the solar cell protective sheet of the invention can be stably manufactured for a long period of time and washability is enhanced.

The olefin-based polymer layers may be provided on both surfaces of the base material film as well as on a single surface of the base material film, and, even in this case, the olefin-based polymer layers are preferably coated on both surfaces of the base material film.

In addition, in a case in which the olefin-based polymer layer has the separate layer described below between the olefin-based polymer layer and the base material film, the olefin-based polymer layer can be formed directly on the base material film or on the separate layer through coating.

The composition for forming the olefin-based polymer layer, which is to form the olefin-based polymer layer, at least includes a binder, which is an olefin-based binder having an elastic modulus of 320 MPa or less, and the composition can be prepared by mixing a coloring pigment, another binder resin, an inorganic oxide filler, a crosslinking agent, additives and the like with a coating solvent as necessary.

[Solvent]

The coating solvent is not particularly limited as long as the respective components that configure the olefin-based polymer layer can be dispersed or dissolved, coated and then removed, water is preferably used, and 60 mass % or more of the solvent included in the composition for forming the olefin-based polymer layer is preferably water. The water-based composition described above is preferable since the composition does not easily apply load to the environment, and, when the fraction of water is 60 mass % or more, the water-based composition is advantageous in terms of explosion proof and safety. The fraction of water in the composition for forming the olefin-based polymer layer is desirably higher from the viewpoint of environmental load, and a case in which the fraction of water with respect to the entire solvent is 70 mass % or more is more preferable.

[Crosslinking Agent]

The composition for forming the olefin-based polymer layer preferably contains a crosslinking agent.

When the composition for forming the olefin-based polymer layer contains a crosslinking agent, the binder resin included in the composition for forming the olefin-based polymer layer is crosslinked, and an adhesive and strong colored layer can be formed, which is preferable.

Examples of the crosslinking agent include epoxy-based crosslinking agents, isocyanate-based crosslinking agents, melamine-based crosslinking agents, carbodiimide-based crosslinking agents, oxazoline-based crosslinking agents and the like. Among the above, the oxazoline-based crosslinking agents is particularly preferable from the viewpoint of securing adhesiveness to the sealing material of the solar cell module after the solar cell module is aged in a hot and humid environment.

Specific examples of the oxazoline-based crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), bis-(2-oxazolinyl cyclohexane) sulfide, bis-(2-oxazolinyl norbornane) sulfide and the like. Furthermore, (co)polymers of the above compounds can be preferably used as well.

In addition, a commercially available product may be used as the oxazoline-based crosslinking agent, and examples thereof that can be used include EPOCROS K2010E, K2020E, K2030E, WS500, WS700 (all EPOCROS series manufactured by Nippon Shokubai Co., Ltd.) and the like.

The content of the crosslinking agent with respect to the total mass of the solid content of the composition for forming the olefin-based polymer layer is preferably 5 mass % to 50 mass %, and more preferably 20 mass % to 40 mass % with respect to the total mass of the water-based binder. When the content of the crosslinking agent is set to 5 mass % or more, a sufficient crosslinking effect can be obtained, and it is possible to suppress a decrease in the strength of the olefin-based polymer layer or poor adhesion. On the other hand, when the content is 50 mass % or less, it is possible to prevent the degradation of the pot life of the composition for forming the olefin-based polymer layer.

The composition for forming the olefin-based polymer layer can be coated on the base material film using a well-known method, for example, a gravure coater or a bar coater.

In a case in which the composition for forming the olefin-based polymer layer includes a coloring pigment, the volume fraction of the coloring pigment with respect to the binder resin is 50% to 200% from the viewpoint of reflection performance and film strength, and the composition for forming the olefin-based polymer layer is preferably coated on the base material film so that the coated thickness becomes 1 μm to 20 μm. In addition, the composition is preferably coated so that the coating amount of the coloring pigment becomes 3 g/m² to 20 g/m².

(Separate Layer)

The protective sheet for a solar cell of the invention includes the olefin-based polymer layer on the base material film, and may include at least one separate layer between the olefin-based polymer layer and the base material film.

Meanwhile, an aspect in which the olefin-based polymer layer is in direct contact with the base material film is also preferable from the viewpoint of the reduction of manufacturing costs and an object of further reducing the thickness. That is, the method for manufacturing a solar cell protective sheet of the invention also preferably includes a step of directly coating the composition for forming the olefin-based polymer layer on the base material film as the composition for forming the basecoat layer from the above viewpoint.

When the protective sheet for a solar cell includes the separate layer between the base material film and the olefin-based polymer layer, it is possible to further enhance the adhesion between the base material film and the olefin-based polymer layer.

In the protective sheet for a solar cell of the invention, the separate layer is preferably a basecoat layer, that is, the separate layer is preferably formed through coating. That is, the method for manufacturing a solar cell protective sheet of the invention preferably includes a step of coating the composition for forming the basecoat layer on the base material film before the step of coating the composition for forming the olefin-based polymer layer.

Meanwhile, in the protective sheet for a solar cell of the invention, an aspect in which the separate layer is made only of an inorganic substance other than the inorganic oxide or an organic substance is also preferable. That is, an aspect in which the separate layer does not include the inorganic oxide is also preferable. For example, the separate layer is preferably formed using a method other than the deposition of the inorganic oxide, for example, coating. In addition, in a case in which the separate layer is formed through coating, an aspect in which fine particles of the inorganic oxide and the like are not included is also preferable.

Hereinafter, a case in which the protective sheet for a solar cell of the invention includes a basecoat layer, which is a preferable aspect of the separate layer, will be described.

The basecoat layer can be formed by coating a composition for forming the basecoat layer on the base material film.

The composition for forming the basecoat layer preferably contains at least a water-based binder.

Examples of the water-based binder include polyester, polyurethane, acrylic resins, polyolefin and the like, and, in the protective sheet for a solar cell of the invention, the main component of the separate layer is preferably a polyester-based resin.

Furthermore, the protective sheet for a solar cell may contain an epoxy-based crosslinking agent, an isocyanate-based crosslinking agent, a melamine-based crosslinking agent, a carbodiimide-based crosslinking agent, an oxazoline-based crosslinking agent, an anionic or nonionic surfactant, a filler such as silica, and the like in addition to the water-based binder.

The content of the water-based binder with respect to the total mass of the solid content of the composition for forming the basecoat layer is preferably 50 mass % to 100 mass %, and more preferably 70 mass % to 100 mass %.

The basecoat layer may contain a variety of additives, such as an inorganic oxide filler which will be described below, fine particles of a substance other than the inorganic oxide filler, an ultraviolet absorbent, an antioxidant and a surfactant.

The method for coating the water-based composition for forming the basecoat layer is not particularly limited.

As the coating method, for example, a gravure coater or a bar coater can be used.

Regarding the coating amount, the water-based composition for forming the basecoat layer is preferably coated on the base material film so that the layer thickness of the dried coated composition becomes preferably less than 10 μm, more preferably 0.05 μm to 2 μm, and particularly preferably 0.1 μm to 1.5 μm from the viewpoint of adhesion and surface state.

Water is used as the coating solvent for the water-based composition for forming the basecoat layer, and 60 mass % or more of the solvent included in the water-based composition for forming the basecoat layer is preferably water. The water-based composition is preferable since the composition does not easily apply load to the environment, and, when the fraction of water is 60 mass % or more, the water-based composition is advantageous in terms of explosion proof and safety.

The fraction of water in the water-based composition for forming the basecoat layer is desirably higher from the viewpoint of environmental load, and a case in which the fraction of water with respect to the entire solvent is 70 mass % or more is more preferable.

(Weather-Resistant Layer)

The protective sheet for a solar cell of the invention preferably further includes a weather-resistant layer containing at least one of a fluororesin and a silicone-acryl composite resin on a surface of the base material film opposite to a surface on which the olefin-based polymer layer is disposed.

Examples of the fluororesin included in the composition for forming the weather-resistant layer, which is to form the weather-resistant layer, include chlorotrifluoroethylene, tetrafluoroethylene, hexafluoropropylene, vinylidene fluoride, trifluoroethylene, chlorotrifluoroethylene and ethylene copolymer, tetrafluoroethylene and perfluoroalkyl vinyl ether copolymer. Among the above, chlorotrifluoroethylene and vinyl ether copolymer which is copolymerized with a vinyl-based compound is preferable from the viewpoint of solubility and weather resistance.

Examples of the fluororesin included in the composition for forming the weather-resistant layer include OBBLIGATO SW0011F [manufactured by AGC Coat-Tech Co., Ltd.].

The content of the fluororesin with respect to the total mass of the solid content of the composition for forming the weather-resistant layer is preferably 40 mass % to 90 mass % and more preferably 50 mass % to 80 mass % from the viewpoint of weather resistance and film strength.

Examples of the silicone-acryl composite resin included in the composition for forming the weather-resistant layer include CERANATE WSA1060 and WSA1070 (all manufactured by DIC Corp.), and H7620, H7630 and H7650 (all manufactured by Asahi Kasei Chemicals Corp.).

The content of the silicone-acryl composite resin with respect to the total mass of the solid content of the composition for forming the weather-resistant layer is preferably 40 mass % to 90 mass % and more preferably 50 mass % to 80 mass % from the viewpoint of weather resistance and film strength.

The coating amount of the composition for forming the weather-resistant layer is preferably set to 0.5 g/m² to 15 g/m², and more preferably set to 3 g/m² to 7 g/m² from the viewpoint of weather resistance and adhesion to the base material film.

The method for forming the composition for forming the weather-resistant layer is not particularly limited, but the composition is preferably formed through coating.

Particularly, the manufacturing method of the invention preferably includes a step of coating the composition for forming the weather-resistant layer including at least one of a fluororesin and a silicone-acryl composite resin on a surface of the base material film opposite to a surface on which the composition for forming the olefin-based polymer layer is coated.

As the coating method, for example, a gravure coater or a bar coater can be used.

Water is preferably used as the coating solvent for the composition for forming the weather-resistant layer, and 60 mass % or more of the solvent included in the composition for forming the weather-resistant layer is preferably water. The water-based composition is preferable since the composition does not easily apply load to the environment, and, when the fraction of water is 60 mass % or more, the water-based composition is advantageous in terms of explosion proof and safety.

The fraction of water in the composition for forming the weather-resistant layer is desirably higher from the viewpoint of environmental load, and a case in which the fraction of water with respect to the entire solvent is 70 mass % or more is more preferable.

The weather-resistant layer may contain a variety of additives, such as an inorganic oxide filler, fine particles of a substance other than the inorganic oxide filler, an ultraviolet absorbent, an antioxidant and a surfactant.

The layer thickness of the weather-resistant layer is preferably 0.5 μm to 15 μm, and more preferably 3 μm to 7 μm. When the film thickness is 0.5 μm or more, sufficient weather resistance can be developed, and, when the film thickness is 15 μm or less, it is possible to suppress the degradation of the surface state.

Meanwhile, the weather-resistant layer may be a single layer or a laminate of two or more layers. The protective sheet for a solar cell of the invention is preferably configured by stacking two weather-resistant layers.

<Characteristics of the Protective Sheet for a Solar Cell>

(Light Reflectivity)

The surfaces of the protective sheet for a solar cell of the invention on which the olefin-based polymer layer is disposed (outermost surfaces) preferably have a light reflectivity of 70% or more at a wavelength of 550 nm. When the light reflectivity is 70% or more, it is possible to sufficiently return light of solar light, which has transmitted through cells of the solar cell, to the cells, thereby increasing the power generation efficiency, which is preferable. The light reflectivity is preferably 75% or more, and particularly preferably 80% or more.

[Back Sheet Member for Solar Cell and Back Sheet for Solar Cell]

The back sheet member for a solar cell or back sheet for a solar cell of the invention includes the protective sheet for a solar cell of the invention. In addition, the protective sheet for a solar cell of the invention may be used as it is as the back sheet member for a solar cell or back sheet for a solar cell of the invention.

[Laminate for Solar Cell]

The laminate for a solar cell of the invention includes the protective sheet for a solar cell and the polymer layer which is directly adhered to at least the surface of the protective sheet for a solar cell on the olefin-based polymer layer side and includes an ethylene-vinyl acetate copolymer.

Since the protective sheet for a solar cell of the invention is favorably adhesive to the sealing material (for example, EVA) used in the solar cell module on the surface on the olefin-based polymer layer side, the protective sheet and the sealing material can be adhered to each other without an adhesive layer or the like. In addition, in a laminate for a solar cell in which a sealing material such as an ethylene-vinyl acetate copolymer is directly adhered to at least the surface of the protective sheet for a solar cell on the olefin-based polymer layer side, the adhesion between the sealing material and the protective sheet is favorable for a long period of time even after the laminate is aged in a hot and humid environment.

The above laminate for a solar cell may be used as a sealing material that seals a solar cell element as it is, or may be used as apart of the sealing material of the solar cell module.

[Solar Cell Module]

The protective sheet for a solar cell of the invention is preferable for manufacturing of a solar cell module.

The solar cell module is configured by, for example, disposing a solar cell element that converts the light energy of solar light into electric energy between a transparent substrate on which solar light enters and the back sheet for a solar cell of the invention, and sealing the gap between the substrate and the back sheet using a sealing material such as ethylene-vinyl acetate copolymer.

Members other than the solar cell module, the solar battery cell and the back sheet are described in detail in, for example, “Constituent materials of solar power generation system” (edited by Eiichi Sugimoto, Kogyo Chosakai Publishing Co., Ltd., published in 2008).

A first aspect of the solar cell module of the invention includes a transparent front substrate on a side on which sun light enters, a solar cell element, a sealing material that seals the solar cell element, and a back sheet for a solar cell which is disposed on the sealing material on an opposite side to the front substrate and is adhered to the sealing material, in which the back sheet for a solar cell includes the back sheet member for a solar cell or the back sheet for a solar cell of the invention, and the olefin-based polymer layer in the back sheet member for a solar cell or the back sheet for a solar cell is directly adhered to the sealing material.

A second aspect of the solar cell module of the invention includes a transparent front substrate on a side on which sun light enters, a solar cell element, a sealing material that seals the solar cell element, and a back sheet for a solar cell which is disposed on the sealing material on an opposite side to the front substrate and is adhered to the sealing material, in which the laminate for a solar cell of the invention is included as the back sheet for a solar cell and the sealing material.

The solar cell module can be preferably configured by providing the solar cell element, the sealing material that seals the solar cell element, a surface protective member that adheres to the sealing material and protects a light-receiving surface side, and a rear surface protective member that adheres to the sealing material and protects an opposite side to the light-receiving surface, including ethylene-vinyl acetate copolymer (EVA) in the sealing material, using the back sheet for a solar cell of the invention as the rear surface protective member, and directly adhering the colored layer in the back sheet for a solar cell to the sealing material. When the solar cell module is configured in the above manner, the back sheet for a solar cell is adhered to EVA for a long period of time even in a hot and humid environment, and it is possible to make the solar cell module serve for a long service life.

The transparent front substrate simply needs to be light transmissible so as to allow solar light to transmit through, and can be appropriately selected from base materials that allow light to transmit through. From the viewpoint of power generation efficiency, the light transmittance is preferably higher, and, for example, a glass substrate, a transparent resin such as an acrylic resin, or the like can be preferably used as the substrate.

As the solar cell element, it is possible to apply a variety of well-known solar cell elements, such as silicon-based elements such as single-crystal silicon, polycrystal silicon and amorphous silicon; III-V group or II-VI group compound semiconductor-based elements such as copper-indium-gallium-selenium, copper-indium-selenium, cadmium-tellurium and gallium-arsenic.

### EXAMPLES

Hereinafter, the characteristics of the invention will be more specifically described using examples.

Materials, use amounts, fractions, treatment contents, treatment sequences and the like described in the following examples can be appropriately modified within the scope of the purport of the invention. Therefore, the ranges for the invention are not supposed to be restrictively interpreted by specific examples described below. Meanwhile, unless particularly otherwise described, “parts” are by mass.

Meanwhile, the volume average particle diameter is measured using MICROTRAC FRA manufactured by Honeywell Japan Inc.

### Example 1

### Production of a Base Material Film

—Synthesis of Polyester—

A slurry of 100 kg of high-purity terephthalic acid (manufactured by Mitsui Chemicals, Inc.) and 45 kg of ethylene glycol (manufactured by Nippon Shokubai Co., Ltd.) was sequentially supplied over 4 hours to an esterification tank which had been loaded with approximately 123 kg of bis(hydroxyethyl) terephthalate in advance and held at a temperature of 250° C. and a pressure of 1.2×10⁵ Pa, and an esterification reaction was caused over additional one hour even after the end of the supply. After that, 123 kg of the obtained esterification reaction product was transferred to a polycondensation reaction tank.

Subsequently, 0.3 mass % of ethylene glycol with respect to a polymer to be obtained was added in the polycondensation reaction tank to which the esterification reaction product had been transferred. After 5 minutes of stirring, an ethylene glycol solution of cobalt acetate and manganese acetate was added so that the contents became 30 ppm and 15 ppm with respect to the polymer to be obtained respectively. After another 5 minutes of stirring, an ethylene glycol solution of 2 mass % of a titanium alkoxide compound was added so that the content became 5 ppm with respect to the polymer to be obtained. After 5 minutes, an ethylene glycol solution of 10 mass % of diethyl phosphono ethyl acetate was added so that the content became 5 ppm with respect to the polymer to be obtained. After that, the temperature of the reaction system was gradually increased from 250° C. to 285° C., and the pressure was decreased to 40 Pa while stirring the low polymer at 30 rpm. The times elapsed for the final temperature and the final pressure to be reached were both set to 60 minutes. When the stirring torque reached a predetermined value, the reaction system was purged with nitrogen gas, returned to normal pressure, and the polycondensation reaction was stopped. In addition, the resulting product was ejected into cold water in a strand form, and immediately cut, thereby producing polymer pellets (having a diameter of approximately 3 mm and a length of approximately 7 mm). Meanwhile, the time elapsed for the stirring torque to reach the predetermined value from the beginning of depressurization was 3 hours.

Here, as the titanium alkoxide compound, the titanium alkoxide compound (content of Ti=4.44 mass %) synthesized in Example 1 in paragraph number [0083] of JP-A-2005-340616 was used.

—Solid-State Polymerization—

The above-obtained pellets were held in a vacuum container held at 40 Pa at a temperature of 220° C. for 30 hours, thereby carrying out solid-state polymerization.

—Formation of the Base—

The pellets that had been subjected to solid-state polymerization as described above were melted at 280° C., and cast on a metal drum, thereby producing unstretched bases having a thickness of approximately 3 mm. After that, the bases were stretched in the vertical direction at 90° C. by 3 times, and further stretched in the horizontal direction at 120° C. by 3.3 times. Thereby, biaxial stretched polyethylene terephthalate films (hereinafter referred to as “PET base material films”) having a thickness of 250 μm were obtained.

### Formation of the Basecoat Layer and the Colored Layer

—Preparation of a Coating Liquid for the Basecoat Layer 1—

The components of the following composition were mixed so as to prepare a coating liquid for the basecoat layer 1.

(Composition for the Coating Liquid for the Basecoat Layer 1)

| | | |
|---|---|---|
| Water dispersion of a polyester resin | 48 | parts by mass |
| [VYLONAL 1245 manufactured by Toyobo Co., | | |
| Ltd., solid content: 30 mass %] | | |
| Fine particles of a PMMA resin | 0.5 | parts by mass |
| [MP-1000 manufactured by Soken Chemical | | |
| Engineering Co., Ltd., solid content: | | |
| 100 mass %] | | |
| Oxazoline compound | 3 | parts by mass |
| [EPOCROS WS-700 manufactured by Nippon | | |
| Shokubai Co., Ltd., solid content: | | |
| 25 mass %] | | |
| Carbodiimide compound | 4.3 | parts by mass |
| [CARBODILITE V-02-L2 manufactured by | | |
| Nisshinbo Industries, Inc., solid content: | | |
| 40 mass %] | | |
| Polyoxy alkylene alkyl ether | 0.15 | parts by mass |
| [NAROACTY CL-95 manufactured by Sanyo | | |
| Chemical Industries, Ltd., solid content: | | |
| 100 mass %] | | |
| Distilled water | 935 | parts by mass |

—Preparation of a White Inorganic Fine Particle Dispersion 1—

The components of the following composition were mixed, and the mixture was subjected to a dispersion treatment using a dyno mill-type disperser, thereby obtaining a white inorganic fine particle dispersion 1 having a volume average particle diameter of 0.42 μm.

(Composition of White Inorganic Fine Particle Dispersion 1)

| | | |
|---|---|---|
| Titanium dioxide | 765 | parts by mass |
| [TIPAQUE R-780-2 manufactured by Ishihara | | |
| Sangyo Kaisha, Ltd., solid content: 100 mass %; | | |
| white pigment] | | |
| 10% aqueous solution of polyvinyl alcohol | 383 | parts by mass |
| (PVA-105) | | |
| [PVA-105 manufactured by Kuraray Co., Ltd., | | |
| solid content: 100 mass %] | | |
| Surfactant | 9.2 | parts by mass |
| [DEMOL EP manufactured by Kao Corporation, | | |
| solid content: 25 mass %] | | |
| Distilled water | 363 | parts by mass |

—Preparation of a Silica Dispersion Liquid 1—

The components of the following composition were mixed, and the mixture was subjected to a dispersion treatment using an altimizer disperser, thereby preparing a silica dispersion liquid 1 (concentration: 10%).

| | |
|---|---|
| Distilled water | 900 parts by mass |
| Silica particles | 100 parts by mass |
| [OX-50 manufactured by Nippon Aerosil Co., Ltd.] | |

—Preparation of a Coating Liquid for Colored Layer 1—

The components of the following composition were mixed, thereby preparing a coating liquid for the colored layer 1.

(Composition of Coating Liquid for Colored Layer 1)

| | | |
|---|---|---|
| The above-obtained white inorganic fine | 1520 | parts by mass |
| particle dispersion 1 | | |
| Polyolefin resin water dispersion <<binder>> | 823 | parts by mass |
| [ARROW BASE SE-1010 manufactured by | | |
| Unitika Ltd., solid content: 20 mass %] | | |
| Polyoxy alkylene alkyl ether | 0.71 | parts by mass |
| [NAROACTY CL-95 manufactured by Sanyo | | |
| Chemical Industries, Ltd., solid content: | | |
| 100 mass %] | | |
| Oxazoline compound | 84.62 | parts by mass |
| [EPOCROS WS-700 manufactured by Nippon | | |
| Shokubai Co., Ltd., solid content: | | |
| 25 mass %] | | |
| The above-obtained silica dispersion liquid 1 | 56.4 | parts by mass |
| Distilled water | 413 | parts by mass |
| Ether-based polyurethane | 5.48 | parts by mass |
| [SUPER FLEX 110 manufactured by Daiichi | | |
| Kogyo Seiyaku Co., Ltd., solid content: | | |
| 30 mass %] | | |
| (An 1% equivalent of the solid content of the | | |
| polyolefin resin water dispersion was added) | | |

—Formation of a Basecoat Layer and a Colored Layer—

A single surface of a PET base material film was transported at a transportation rate of 80 m/minute, subjected to a corona discharge treatment under a condition of 730 J/m², and then the coating liquid for basecoat layer 1 was coated using a bar coating method so that the dried weight became 124 mg/m². In addition, the coating liquid was dried at 180° C. for 1 minute so as to form a basecoat layer. Subsequently, the coating liquid for colored layer 1 was coated on the basecoat layer using a bar coating method so that the dried weight became 10.5 g/m², and then dried at 170° C. for 1 minute, thereby obtaining a white PET film having a basecoat layer having a dried thickness of 0.1 μm and a white colored layer (olefin-based polymer layer) having a dried thickness of 8 μm stacked in this order on the single surface of the PET base material film.

—(A) Washability—

An SUS plate was immersed in a coating liquid for a white layer 1 produced in the above manner, gently lifted, and stood still in a thermo box at 30° C. for 1 hour in a state of being stood at 90°, thereby producing a dried membrane. After that, the membrane was wetted using flowing water, a load of 500 gf/cm² was applied to a cellulose wiper [BEMCOT M-3 manufactured by Asahi Kasei Fibers Corporation], and the cellulose wiper was made to reciprocate, thereby evaluating washability.

The membranes were ranked based on the evaluated washability according to the following evaluation criteria. Ranks 3 or higher are in a practically permissible range, and Ranks 4 and 5 are in a more preferable practical range.

5: Contaminants were removed in 80% or more of a friction area with a 1 round of reciprocation

4: Contaminants were removed in 80% or more of the friction area with 2 to 5 rounds of reciprocation

3: Contaminants were removed in 80% or more of the friction area with 6 to 20 rounds of reciprocation

2: Contaminants were removed in 70% or more of the friction area with 20 rounds of reciprocation

1: Contaminants were removed in less than 70% of the friction area with 20 rounds of reciprocation

The obtained results were described in Table 1.

### Formation of the Weather-Resistant Layer

The following first weather-resistant layer and the following first weather-resistant layer were formed in this order on an opposite surface to a surface of the white base material PET film on which the white colored layer was coated.

—Preparation of White Inorganic Fine Particle Dispersion 2—

The components described in the following composition of the white inorganic fine particle dispersion 2 were mixed, and the mixture was subjected to a dispersion treatment for 1 hour using a dyno mill-type disperser, thereby obtaining a fine particle dispersion 2 having a volume average particle diameter of 0.42 μm.

(Composition of the White Inorganic Fine Particle Dispersion 2)

| | | |
|---|---|---|
| Titanium dioxide (white pigment, volume average | 7.98 | parts by mass |
| particle diameter 0.42 μm) | | |
| [TIPAQUE R-780-2 manufactured by Ishihara | | |
| Sangyo Kaisha, Ltd., solid content: | | |
| 100 mass %] | | |
| 10% aqueous solution of polyvinyl alcohol | 10 | parts by mass |
| (PVA-105) | | |
| [PVA-105 manufactured by Kuraray Co., | | |
| Ltd., solid content: 100 mass %] | | |
| Surfactant [DEMOL EP manufactured by | 0.1 | parts by mass |
| Kao Corporation, solid content: 25%] | | |
| Distilled water | 1.92 | parts by mass |

—Preparation of a Coating Liquid for Forming the First Weather-Resistant Layer—

The respective components described in the following composition of a coating liquid for forming the first weather-resistant layer were mixed, thereby preparing a coating liquid for forming the first weather-resistant layer.

(Composition of the Coating Liquid for Forming the First Weather-Resistant Layer)

| | |
|---|---|
| Acryl/silicone-based binder (silicone-based | 362.3 parts by mass |
| resin, P-1) | |
| [CERANATE WSA-1070 manufactured by DIC | |
| Corp., solid content: 40%] | |
| Carbodiimide compound (crosslinking agent, A-1) | 48.3 parts by mass |
| [CARBODILITE V-02-L2 manufactured by | |
| Nisshinbo Industries, Inc., solid content: 40%] | |
| Surfactant | 9.7 parts by mass |
| [NAROACTY CL-95 manufactured by Sanyo | |
| Chemical Industries, Ltd., solid content: 1%] | |
| The white inorganic fine particle dispersion 2 | 157.0 parts by mass |
| Distilled water | 422.7 parts by mass |

—Formation of the First Weather-Resistant Layer—

The opposite surface to the surface of the white PET film on which the white colored layer was coated was transported at a transportation rate of 80 m/minute, and subjected to a corona discharge treatment under a condition of 730 J/m². After that, the coating liquid for forming the first weather-resistant layer was coated on the surface on which the corona discharge treatment had been carried out so that the amount of the silicone-based resin (P-1) became 3.0 g/m² in terms of the coating amount, and dried at 180° C. for 1 minute, thereby forming a first weather-resistant layer having a dried thickness of 3 μm.

—Preparation of a Coating Liquid for Forming the Second Weather-Resistant Layer—

The respective components described in the following composition of a coating liquid for forming the second weather-resistant layer were mixed, thereby preparing a coating liquid for forming the second weather-resistant layer.

(Composition of the Coating Liquid for Forming the Second Weather-Resistant Layer)

| | |
|---|---|
| Acryl/silicone-based binder (silicone-based | 362.3 parts by mass |
| resin, P-1) | |
| [CERANATE WSA-1070 manufactured by DIC | |
| Corp., solid content: 40%] | |
| Carbodiimide compound (crosslinking agent, A-1) | 24.2 parts by mass |
| [CARBODILITE V-02-L2 manufactured by | |
| Nisshinbo Industries, Inc., solid content: 40%] | |
| Surfactant | 24.2 parts by mass |
| [NAROACTY CL-95 manufactured by Sanyo | |
| Chemical Industries, Ltd., solid content: 1%] | |
| Distilled water | 703.8 parts by mass |

—Formation of the Second Weather-Resistant Layer—

The obtained coating liquid for forming the second weather-resistant layer was coated on the first weather-resistant layer so that the amount of the silicone-based resin (P-1) became 2.0 g/m² in terms of the coating amount, and dried at 180° C. for one minute, thereby forming a second weather-resistant layer having a dried thickness of 2.5 μm.

The basecoat layer and the white colored layer were provided on the single surface of the PET base material film in the above manner, and a protective sheet for a solar cell provided with the first weather-resistant layer and the second weather-resistant layer on the opposite surface of the PET base material film was produced. The protective sheet for a solar cell was used as a protective sheet for a solar cell of Example 1.

### Evaluation of the Protective Sheet for a Solar Cell

The adhesion to the sealing agent, adhesion to sealing agent after aged in a hot and humid environment, reflectivity and weather resistance of the protective sheet for a solar cell of Example 1 were evaluated using the following methods. The obtained results are described in Table 1.

—1. Adhesion to the Sealing Agent Before being Aged in a Hot and Humid Environment—

The protective sheet for a solar cell produced in the above manner was cut into 20 mm-wide×150 mm pieces, thereby preparing two test specimens. The two test specimens were disposed so that the white layers faced each other, an EVA sheet (RC02B, EVA sheet manufactured by Mitsui Chemicals Fabro, Inc.) cut into a 20 mm-wide×100 mm-long piece was sandwiched between the test specimens, and the specimens were hot-pressed using a vacuum laminator (vacuum laminating machine manufactured by Nisshinbo Holdings Inc.), thereby being adhered to the EVA sheet. The adhering conditions at this time were set as follows.

The test specimens were vacuumed at 150° C. for 3 minutes using the vacuum laminator, and then pressed for 10 minutes, thereby being adhered. Thereby, a test specimen for evaluating adhesion having no adhered EVA in a 50 mm portion from one end of two mutually adhered sample specimens and the EVA sheet adhered to the remaining 100 mm portion was obtained.

The EVA-unadhered portion of the obtained test specimen for evaluating adhesion (the portion 50 mm from one end of the specimen) was sandwiched using the top and bottom clips of a TENSILON (RTC-1210A manufactured by ORIENTEC Co., Ltd.), and a tension test was carried out at a peeling angle of 180° and a tension rate of 300 mm/minute, thereby measuring the adhesive force.

The test specimens were ranked based on the measured adhesive forces according to the following evaluation criteria. Among the ranks, Ranks 4 and 5 are in a practically permissible range.

(Evaluation Criteria)

5: Adhesion was extremely favorable (60 N/20 mm or more)

4: Adhesion was favorable (30 N/20 mm to less than 60 N/20 mm)

3: Adhesion was slightly poor (20 N/20 mm to less than 30 N/20 mm)

2: Poor adhesion was caused (10 N/20 mm to less than 20 N/20 mm)

1: Poor adhesion was significant (less than 10 N/20 mm)

—2. Adhesion to the Sealing Agent after Aged in a Hot and Humid Environment—

The protective sheet for a solar cell produced in the above manner was held for 48 hours under environmental conditions of 105° C. and a relative humidity of 100% (aged in a hot and humid environment), then, test specimens were prepared in the same manner as in the adhesion to the sealing agent before being aged in a hot and humid environment, the adhesive force with the EVA sheet was measured, and the test specimens were ranked according to the same evaluation criteria. Meanwhile, regarding the adhesion to the sealing agent after aged in a hot and humid environment, Ranks 3 or higher are in a practically permissible range, and Ranks 4 and 5 are in a more preferable practical range.

—3. Reflectivity—

For the protective sheets for a solar cell produced in the above manner, the reflectivity with respect to light at 550 nm was measured using a spectrophotometer UV-3100 (manufactured by Shimadzu Corporation). The reflectivity of a barium sulfate standard plate was measured as a reference, and the reflectivity of the protective sheet for a solar cell was computed with an assumption that the reflectivity of the barium sulfate standard plate was 100%.

—4. Weather Resistance—

For the protective sheets for a solar cell produced in the above manner, light was radiated for 14 days from the opposite surface of the colored layer under conditions of a BPT temperature of 35° C., a relative humidity of 50% and a radiant illumination of 390 W/m² using a low-temperature cycle xenon weather meter XL75 (manufactured by Suga Test Instruments Co., Ltd.).

b values before and after the radiation were measured using a spectrophotometer CM3700d manufactured by Konica Minolta, Inc., and Δb of 1 or more was evaluated as Δ, and Δb of 1 or less was evaluated as O.

—5. General Evaluation—

The protective sheets for a solar cell produced in the above manner were generally evaluated according to the following evaluation criteria. Among the criteria, Ranks 3 or higher is in a practically permissible range, and Ranks 4 and 5 are in a more preferable practical range.

(Evaluation Criteria)

| | |
|---|---|
| 5: Washability 4 or more | EVA adhesion evaluation 5 |
| 4: Washability 4 or more | EVA adhesion evaluation 4 or more |
| 3: Washability 3 or more | EVA adhesion evaluation 3 or more |
| 2: Washability 2 or more | EVA adhesion evaluation 2 or more |
| 1: Washability 1 or more | EVA adhesion evaluation 1 or more |

### Examples 2 to 6, Comparative Examples 1 to 6

Protective sheets for a solar cell of Examples 2 to 6 and Comparative Examples 1 to 6 were manufactured in the same manner as in Example 1 except that the addition ratio of the ether-based polyurethane [SUPER FLEX 110 manufactured by Daiichi Kogyo Seiyaku Co., Ltd., solid content: 30 mass %] to the coating liquid for the colored layer 1 and the kinds of polyurethane were changed as described below, and, furthermore, the presence of a basecoating liquid, the presence of the weather-resistant layer, the kinds of the pigment, the coating amounts of the pigment and the ratios of the pigment were changed as described in Table 1, and evaluated.

(The Kinds and Main Chain Structures of the Main Binders and the Additive Binders Used in the Respective Examples and the Respective Comparative Examples)

A1: Acryl-based resin [JONCRYL PDX7341 manufactured by BASF Ltd., solid content: 49 mass %]

B1: Ether-based polyurethane [SUPER FLEX 110, manufactured by Daiichi Kogyo Seiyaku Co., Ltd., solid content: 30 mass %]

B2: Carbonate-based polyurethane [SUPER FLEX 460, all manufactured by Daiichi Kogyo Seiyaku Co., Ltd., solid content: 38 mass %]

The evaluation results obtained from the respective examples and the respective comparative examples were described in Table 1.

TABLE 1

| | | | Colored layer | | | | | |
|---|---|---|---|---|---|---|---|---|
| | | | Coloring pigment | | | | Additive binder | |
| | | | | Amount | | | | Addition amount |
| | | | | of | | | | (with respect to |
| | Basecoat | | | pigment | | | | main binder) |
| | layer | Weather-resistant layer | Kind of pigment | [g/m²] | Volume fraction | Main binder | Kind | [mass %] |
| Example 1 | Yes | Yes | Titanium oxide | 8 | 100% | A1 | B1 | 1 |
| Example 2 | Yes | Yes | Titanium oxide | 8 | 100% | A1 | B1 | 3 |
| Example 3 | Yes | Yes | Titanium oxide | 8 | 100% | A1 | B1 | 5 |
| Example 4 | No | Yes | Titanium oxide | 8 | 100% | A1 | B1 | 3 |
| Example 5 | Yes | No | Titanium oxide | 8 | 100% | A1 | B1 | 3 |
| Example 6 | Yes | Yes | Titanium oxide | 4 | 100% | A1 | B1 | 3 |
| Comparative Example 1 | Yes | Yes | Titanium oxide | 8 | 100% | A1 | None | None |
| Comparative Example 2 | Yes | Yes | Titanium oxide | 8 | 100% | A1 | B1 | 9 |
| Comparative Example 3 | Yes | Yes | Titanium oxide | 8 | 100% | A1 | B2 | 1 |
| Comparative Example 4 | Yes | Yes | Titanium oxide | 8 | 100% | A1 | B2 | 3 |
| Comparative Example 5 | Yes | Yes | Titanium oxide | 8 | 100% | A1 | B2 | 5 |
| Comparative Example 6 | Yes | Yes | Titanium oxide | 8 | 100% | A2 | B1 | 5 |

| | Evaluation | | | | | | | |
|---|---|---|---|---|---|---|---|---|
| | | Adhesion to sealing agent | | | | | | |
| | | Before being aged in hot and humid | | After aged in hot and humid | | Reflectivity | | |
| | | environment | | environment | | 550 nm | Weather | General |
| | Washability | [N/20 mm] | Evaluation | [N/20 mm] | Evaluation | [%] | resistance | evaluation |
| Example 1 | 3 | 80 | 5 | 70 | 5 | 82 | ◯ | 3 |
| Example 2 | 4 | 80 | 5 | 70 | 5 | 81 | ◯ | 5 |
| Example 3 | 4 | 60 | 5 | 45 | 4 | 82 | ◯ | 4 |
| Example 4 | 4 | 30 | 4 | 20 | 3 | 82 | ◯ | 3 |
| Example 5 | 4 | 80 | 5 | 70 | 5 | 79 | Δ | 5 |
| Example 6 | 4 | 80 | 5 | 70 | 5 | 65 | ◯ | 5 |
| Comparative | 2 | 60 | 5 | 70 | 5 | 81 | ◯ | 2 |
| Example 1 | | | | | | | | |
| Comparative | 4 | 40 | 4 | 15 | 2 | 80 | ◯ | 2 |
| Example 2 | | | | | | | | |
| Comparative | 2 | 80 | 5 | 70 | 5 | 82 | ◯ | 2 |
| Example 3 | | | | | | | | |
| Comparative | 2 | 80 | 5 | 70 | 5 | 80 | ◯ | 2 |
| Example 4 | | | | | | | | |
| Comparative | 2 | 70 | 5 | 55 | 4 | 79 | ◯ | 2 |
| Example 5 | | | | | | | | |
| Comparative | 4 | 10 | 2 | 10 | 2 | 82 | ◯ | 2 |
| Example 6 | | | | | | | | |

It was found from Table 1 that the protective sheet for a solar cell of the invention was superior to the protective sheets for a solar cell of Comparative Examples particularly in terms of adhesion to the sealing material after aged in a hot and humid environment. Furthermore, it was also found that the protective sheet for a solar cell of the invention was also favorable in terms of adhesion to the sealing material, reflectivity and weather resistance before being aged in a hot and humid environment. That is, when generally evaluated, it was found that the protective sheet for a solar cell of the invention had excellent performances as a back sheet member for a solar cell and as a back sheet for a solar cell.

Meanwhile, the method for manufacturing a solar cell protective sheet of Comparative Example 1 was an aspect in which the additive binder was not used, and it was found that the washability of the manufacturing apparatus was poor.

The solar cell protective sheet of Comparative Example 2 and the method for manufacturing the same was an aspect in which the ether-based polyurethane resin was added as the additive binder in an amount that was equal to or larger than the addition amount regulated by the invention, and it was found that the adhesion to the sealing material after aged in a hot and humid environment was poor.

The methods for manufacturing the solar cell protective sheets of Comparative Examples 3 to 5 were aspects in which a polyurethane resin, which is a carbonate-based resin, was added as the additive binder instead of the ether-based binder in a variety of amounts, and it was found that the washability of the manufacturing apparatus was poor even when the carbonate-based polyurethane resin was used.

Meanwhile, in the evaluation of the adhesion to the sealing material, there was no case in which the forces added in the respective examples and the respective comparative examples caused peeling between other layers in the protective sheets for a solar cell of the respective examples and the respective comparative examples (between the respective weather-resistant layers, between the weather-resistant layer and the base material film, between the base material film and the basecoat layer, between the basecoat layers and between the colored layers, and between the base material film and the colored layer). In addition, the elastic modulus of the olefin-based binder used as the main binder for the colored layer in Examples 1 to 6 and Comparative Examples 1 to 5 were 49.5 MPa.

### Example 101

### Production and Evaluation of a Solar Cell Module

A 3 mm-thick piece of tempered glass, an EVA sheet (SC50B manufactured by Mitsui Chemicals Fabro, Inc.), a crystalline solar battery cell, an EVA sheet (SC50B manufactured by Mitsui Chemicals Fabro, Inc.) and the protective sheet for a solar cell produced in each of the examples were stacked in this order, and hot-pressed using a vacuum laminator (vacuum laminating machine manufactured by Nisshinbo Holdings Inc.), thereby adhering the EVA to the respective members. At this time, the protective sheet for a solar cell of each Example was disposed so that the colored layer came into contact with the EVA sheet. In addition, the adhering method is as follows.

The colored layer and the EVA sheet were vacuumed at 128° C. for 3 minutes using a vacuum laminator, and then pressed for 2 minutes so as to be preliminarily adhered. After that, a principal adhesion treatment was carried out in a dry oven at 150° C. for 30 minutes.

A crystalline solar cell module was produced in the above manner. Power was generated using the obtained solar cell modules, all the solar cells exhibited favorable power generation performances, and were stably operated for a long period of time.

### REFERENCE SIGNS LIST

10 solar cell module
12 second weather-resistant layer
14 first weather-resistant layer
16 base material film
17 separate layer (basecoat layer)
18 olefin-based polymer layer
20 solar cell element
22 sealing material
24 transparent front substrate
31 back sheet member for solar cell (an aspect of protective sheet for solar cell)
32 back sheet for solar cell (another aspect of protective sheet for solar cell)

While the present invention has been described in detail and with reference to specific embodiments thereof, it will be apparent to one skilled in the art that various changes and modifications can be made therein without departing from the spirit and scope thereof.

The present disclosure relates to the subject matter contained in International Application No. PCT/JP2012/055616, filed Mar. 6, 2012; and Japanese Application No. 2011-049492, filed Mar. 7, 2011, the contents of which are expressly incorporated herein by reference in their entirety. All the publications referred to in the present specification are also expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

What is claimed is:

1. A protective sheet for a solar cell comprising:
a base material film; and
an olefin-based polymer layer which is disposed on at least one surface of the base material film and contains at least one olefin-based binder,
wherein the olefin-based polymer layer contains 8 mass % or less of an ether-based polyurethane resin with respect to the olefin-based binder.

2. The protective sheet for a solar cell according to claim 1,
wherein the olefin-based polymer layer is a colored layer containing a coloring pigment.

3. The protective sheet for a solar cell according to claim 2,
wherein a surface of the base material film on which the colored layer is disposed has a light reflectivity of 70% or more at a wavelength of 550 nm, and the coloring pigment is titanium oxide.

4. The protective sheet for a solar cell according to claim 1,
wherein a thickness of the olefin-based polymer layer is 30 μm or less.

5. The protective sheet for a solar cell according to claim 1, further comprising:
at least one separate layer between the olefin-based polymer layer and the base material film.

6. The protective sheet for a solar cell according to claim 1, further comprising:
a weather-resistant layer including at least one of a fluororesin and a silicone-acryl composite resin on a surface of the base material film opposite to a surface on which the olefin-based polymer layer is disposed.

7. A method for manufacturing a protective sheet for a solar cell comprising:
coating a composition for forming an olefin-based polymer layer which contains at least one olefin-based binder, on at least one surface of a base material film or a separate layer which may be arbitrarily provided on the base material film,
wherein the composition for forming the olefin-based polymer layer contains 8 mass % or less of an ether-based polyurethane resin with respect to the olefin-based binder.

8. The method for manufacturing a protective sheet for a solar cell according to claim 7,
wherein the composition for forming the olefin-based polymer layer is a composition for forming a colored layer containing a coloring pigment.

9. The method for manufacturing a protective sheet for a solar cell according to claim 7,
wherein the coloring pigment is titanium oxide.

10. The method for manufacturing a protective sheet for a solar cell according to claim 7, further comprising:
coating a composition for forming a basecoat layer on the base material film before coating the composition for forming the olefin-based polymer layer.

11. The method for manufacturing a protective sheet for a solar cell according to claim 7, further comprising:
coating a composition for forming a weather-resistant layer including at least one of a fluororesin and a silicone-acryl composite resin on a surface of the base material film opposite to a surface on which the composition for forming the olefin-based polymer layer is coated.

12. The method for manufacturing a protective sheet for a solar cell according to claim 7,
wherein a content of the ether-based polyurethane resin included in the composition for forming the olefin-based polymer layer is 2 mass % to 5 mass % with respect to the olefin-based binder.

13. The method for manufacturing a protective sheet for a solar cell according to claim 7,
wherein the olefin-based binder included in the composition for forming the olefin-based polymer layer has an elastic modulus of 320 MPa or less.

14. A protective sheet for a solar cell manufactured by coating a composition for forming an olefin-based polymer layer which contains at least one olefin-based binder, on at least one surface of a base material film or a separate layer which may be arbitrarily provided on the base material film, wherein the composition for forming the olefin-based polymer layer contains 8 mass % or less of an ether-based polyurethane resin with respect to the olefin-based binder.

15. Aback sheet member for a solar cell or aback sheet for a solar cell including a protective sheet for a solar cell, wherein the protective sheet comprises a base material film; and an olefin-based polymer layer which is disposed on at least one surface of the base material film and contains at least one olefin-based binder, in which the olefin-based polymer layer contains 8 mass % or less of an ether-based polyurethane resin with respect to the olefin-based binder.

16. A laminate for a solar cell comprising:
a protective sheet for a solar cell comprising a base material film; and an olefin-based polymer layer which is disposed on at least one surface of the base material film and contains at least one olefin-based binder, in which the olefin-based polymer layer contains 8 mass % or less of an ether-based polyurethane resin with respect to the olefin-based binder; and
a polymer layer which is in direct contact with at least a surface of the protective sheet for a solar cell on the olefin-based polymer layer side and includes an ethylene-vinyl acetate copolymer.

17. A solar cell module comprising:
a transparent front substrate on a side on which sun light enters;
a solar cell element;
a sealing material that seals the solar cell element; and
a back sheet for a solar cell which is disposed on the sealing material on an opposite side to the front substrate and is adhered to the sealing material,
wherein the back sheet for a solar cell includes a back sheet member for a solar cell or a back sheet for a solar cell, and the olefin-based polymer layer in the back sheet member for a solar cell or the back sheet for a solar cell is directly adhered to the sealing material, and
the back sheet member for a solar cell or the back sheet for a solar cell includes a protective sheet for a solar cell, in which the protective sheet comprises a base material film; and an olefin-based polymer layer which is disposed on at least one surface of the base material film and contains at least one olefin-based binder, in which the olefin-based polymer layer contains 8 mass % or less of an ether-based polyurethane resin with respect to the olefin-based binder.

18. A solar cell module comprising:
a transparent front substrate on a side on which sun light enters;
a solar cell element;
a sealing material that seals the solar cell element; and
a back sheet for a solar cell which is disposed on the sealing material on an opposite side to the front substrate and is adhered to the sealing material,
wherein a laminate for a solar cell is included as the back sheet for a solar cell and the sealing material, and
the laminate for a solar cell comprises a protective sheet for a solar cell comprising a base material film; and an olefin-based polymer layer which is disposed on at least one surface of the base material film and contains at least one olefin-based binder, in which the olefin-based polymer layer contains 8 mass % or less of an ether-based polyurethane resin with respect to the olefin-based binder; and a polymer layer which is in direct contact with at least a surface of the protective sheet for a solar cell on the olefin-based polymer layer side and includes an ethylene-vinyl acetate copolymer.
